(19) United States
(12) Patent Application Publication
(10) Pub. No.: US 2025/0389831 A1
(43) Pub. Date: Dec. 25, 2025

(54) UNDERWATER DETECTION DEVICE, AND FAILURE DETERMINATION METHOD OF TRANSDUCER

(71) Applicant: Furuno Electric Co., Ltd., Nishinomiya (JP)

(72) Inventors: Keita TAKARIKI, Nishinomiya (JP); Daisuke NISHIKUBO, Takarazuka (JP)

(21) Appl. No.: 19/308,036

(22) Filed: Aug. 22, 2025

Related U.S. Application Data
(63) Continuation of application No. PCT/JP2024/010111, filed on Mar. 14, 2024.

(30) Foreign Application Priority Data
Mar. 17, 2023 (JP) 2023-043304

(51) Int. Cl. G01S 7/52; G01S 7/524; G01S 15/96; G08B 21/18

(52) U.S. Cl. CPC G01S 7/52004; G01S 7/524; G08B 21/182; G01S 15/96

(57) ABSTRACT

To provide an underwater detection device, a transducer failure determination method, and a program capable of quickly and stably determining a transducer failure. A fish finder (underwater detection device) includes a transmission voltage measuring circuit for measuring a transmission voltage supplied to a transducer, a transmission current measuring circuit for measuring a transmission current supplied to the transducer, and a control circuit. The control circuit calculates the impedance of the transducer from the transmission voltage and the transmission current, and determines that the transducer has failed based on determining that the transducer is not normal in both of a first determination process for determining whether the transducer is normal or not based on the impedance and a second determination process for determining whether the transducer is normal or not based on an echo strength.

### CROSS-REFERENCE TO RELATED APPLICATION

This application is a continuation application of PCT International Application No. PCT/JP2024/010111, which was filed on Mar. 14, 2024, and which claims priority to Japanese Patent Application No. JP2023-043304 filed on Mar. 17, 2023, the entire disclosures of each of which are herein incorporated by reference for all purposes.

### TECHNICAL FIELD

The present disclosure relates to an underwater detection device for detecting underwater conditions, a failure determination method of a transducer executed by the underwater detection device, and a program for making a control circuit of the underwater detection device execute a predetermined function.

### BACKGROUND

Conventionally, an underwater detection device for detecting underwater conditions has been known. In the underwater detection device, ultrasonic waves are transmitted into the water and reflected waves are received. Echo data corresponding to the intensity of the received reflected waves are generated, and an echo image is displayed based on the generated echo data.

In this type of underwater detection device, defects in the underwater detection device are determined from the viewpoint of quality and property maintenance. In this determination, for example, the transmission voltage and transmission current supplied to a transducer are measured, and the impedance of the transducer is calculated from the measured transmission voltage and transmission current. If the calculated impedance is abnormally low or too high compared to a predetermined value, it is presented.

In the above determination method, since the determination criterion of the defect is whether the impedance of the transducer is abnormally low or high, it is not possible to determine the occurrence of the failure unless the defect is advanced considerably.

### SUMMARY

The present disclosure provides an underwater detection device, and a method for determining the failure of a transducer which may determine the failure of the transducer early and stably.

A first aspect of the present disclosure relates to an underwater detection device. The underwater detection device comprises processing circuitry. The processing circuitry measures a transmission voltage and a transmission current supplied to the transducer, calculates the impedance of the transducer from the transmission voltage and the transmission current measured in an actual operation, and determines that the transducer has failed based on determining that the transducer is not normal in both of a first determination process for determining whether the transducer is normal or not based on the impedance and a second determination process for determining whether the transducer is normal or not based on an echo intensity based on a received signal from the transducer.

The impedance of the transducer and the echo intensity based on the received signal are subject to change depending on the environment in which the transducer is used, such as underwater conditions. Therefore, when the failure determination of the transducer is made only by either the determination based on the impedance or the determination based on the echo intensity, the failure determination may be accurately made only by whether the impedance or the echo intensity is abnormally high or low compared with the normal value.

On the other hand, according to the underwater detection device and according to this embodiment, as described above, it is determined that a failure has occurred in the transducer based on the fact that the transducer may not be determined to be normal in the first determination process based on the impedance of the transducer and the transducer may not be determined to be normal in the second determination process based on the echo intensity. As described above, since the two kinds of determinations are used in a complementary manner, it is possible to determine the existence of a failure stably and appropriately in the transducer without rigidly setting each criterion. Therefore, it is possible to determine quickly and stably the failure in the transducer.

A second aspect of the present disclosure relates to a failure determination method of the transducer executed by an underwater detection device. According to this aspect, the failure determination method of the transducer measures the transmission voltage and the transmission current supplied to the transducer in an actual operation, calculates the impedance of the transducer from the transmission voltage and the transmission current, and determines that a failure has occurred in the transducer based on the determination that the transducer is not normal in both a first determination process in which the transducer is normal or not is determined based on the impedance and a second determination process in which the transducer is normal or not is determined based on the echo intensity based on the received signal from the transducer.

According to the failure determination method of the transducer, according to this embodiment, the same effect as the first embodiment may be achieved.

The effect or significance of the present disclosure will be further clarified by the description of the following embodiments. However, the following embodiments are only examples of the embodiment of the present disclosure, and the present disclosure is not limited in any way to those described in the following embodiments.

### BRIEF DESCRIPTION OF DRAWINGS

FIG. 1 is a diagram showing the use of a fish finder according to an embodiment.

FIG. 2 is a block diagram showing the configuration of a fish finder according to an embodiment.

FIG. 3 is a flowchart showing a threshold range setting process executed by the control circuit during an initial operation according to an embodiment.

FIG. 4 is a flowchart showing an initial echo intensity setting process according to an embodiment.

FIG. 5 is a flowchart showing a first determination process for determining whether a transducer is normal or not based on the impedance of the transducer according to the embodiment.

FIG. 6 is a flowchart showing a second determination process for determining whether a transducer is normal or not based on the echo intensity acquired from the received signal of the transducer according to the embodiment.

FIG. 7A and FIG. 7B are flowcharts showing the notification process in the control circuit.

FIG. 8 is a flowchart showing the first determination process for determining whether the transducer is normal or not based on the impedance of the transducer according to the modified example.

FIG. 9 is a flowchart showing the second determination process for determining whether the transducer is normal or not based on the echo intensity acquired from the received signal of the transducer according to the modified example.

### DETAILED DESCRIPTION

Embodiments of the disclosure will now be described with reference to the drawings. In the following embodiments, a fish finder is shown as an example of an underwater detection device.

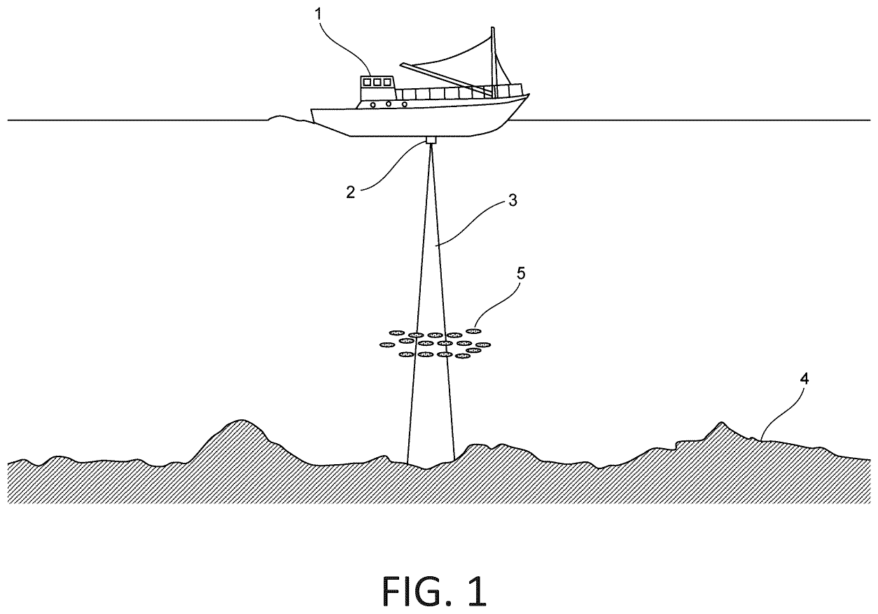

FIG. 1 is a diagram showing the use mode of the fish finder.

In this embodiment, a transducer 2 is installed on the bottom of a ship 1, and a transmission beam 3 (ultrasonic wave) is transmitted from the transducer 2 into the water. The transmission beam 3 has a conical shape with a small top angle, and is transmitted in a pulse shape in the direction just below. The transmission beam 3 is reflected by a water bottom 4 and a fish group 5, and reflected waves (echoes) are received by the transducer 2. Echo data in which the signal intensity (echo intensity) of the received signal is distributed in the detection range in a bathymetric direction is generated by the received signal of reflected waves based on the transmission of one transmission beam 3.

By accumulating echo data for a predetermined period, an echo image showing the distribution of the signal intensity (echo intensity) in the bathymetric direction is generated. The echo image includes the intensity distribution of the echo from each object. The generated echo image in the water is displayed on a display unit installed in the wheelhouse or the like of the ship 1. Thus, the user may confirm the object (water bottom 4, fish group 5, etc.) existing in the water.

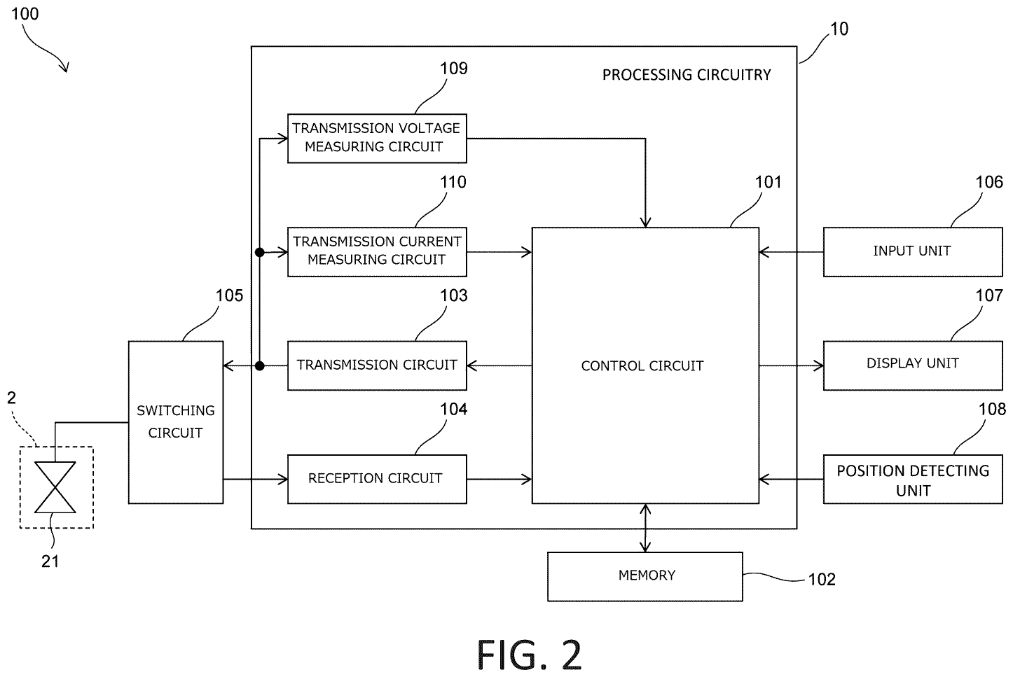

FIG. 2 is a block diagram showing the configuration of a fish finder 100.

The fish finder 100 includes processing circuitry 10, a memory 102, a switching circuit 105, an input unit 106, a display unit 107, and a position detecting unit 108, together with the transducer 2 shown in FIG. 1. The processing circuitry 10 includes a control circuit 101, a transmission circuit 103, a reception circuit 104, a transmission voltage measuring circuit 109, and a transmission current measuring circuit 110.

The control circuit 101, the memory 102, the transmission circuit 103, the reception circuit 104, the switching circuit 105, the input unit 106, the display unit 107, the transmission voltage measuring circuit 109, and the transmission current measuring circuit 110 are installed in the wheelhouse or the like of the ship 1. The configuration excluding the transducer 2 may be unitized in one housing, or some components such as the display unit 107 may be separated. The switching circuit 105 is communicatively connected to the transducer 2 by a signal cable.

The transducer 2 includes a transmitting element used for transmitting ultrasonic waves and a receiving element used for receiving ultrasonic waves. In this embodiment, the transmitting element and the receiving element of the transducer 2 are constituted by one ultrasonic oscillator 21.

The transmission circuit 103 generates a transmitting signal for driving the ultrasonic oscillator 21 based on a control signal input received from the control circuit 101, and outputs the generated transmitting signal to the ultrasonic oscillator 21 of the transducer 2 through the switching circuit 105.

More specifically, the control circuit 101 outputs a frequency control signal that has a rectangular amplitude at a predetermined control frequency and a voltage control signal that defines a control voltage to the transmission circuit 103 as the control signal described above. The transmission circuit 103 generates a transmitting signal that has a frequency similar to the control frequency of the input frequency control signal and a transmitting voltage similar to the control voltage of the input voltage control signal. The transmission circuit 103 outputs the generated transmitting signal to the ultrasonic oscillator 21 via the switching circuit 105.

The ultrasonic oscillator 21 transmits an ultrasonic wave (transmission beam 3) into the water based on the input transmitting signal. The ultrasonic oscillator 21 receives the reflected wave of the transmitted ultrasonic wave and outputs a received signal of a size corresponding to the intensity of the reflected wave to the reception circuit 104 through the switching circuit 105. The switching circuit 105 switches the transmission and reception of the signal to the ultrasonic oscillator 21.

The reception circuit 104 includes a filter for extracting the frequency component of the transmission from the received signal from the ultrasonic oscillator 21 and an amplifier circuit for amplifying the received signal. The reception circuit 104 generates echo data indicating the echo intensity for each depth based on the received signal of the frequency component extracted by the filter. Specifically, the reception circuit 104 generates data corresponding to the elapsed time from the timing of transmitting the ultrasonic wave (transmission beam 3) and the intensity of the reflected wave as echo data, and outputs the generated echo data to the control circuit 101.

Here, the elapsed time from the timing of transmitting the ultrasonic wave corresponds to the depth. The intensity of the reflected wave decreases as the depth increases. Accordingly, the reception circuit 104 compensates the intensity of the reflected wave that attenuates in accordance with the elapsed time and outputs the echo data compensated for the intensity to the control circuit 101.

The control circuit 101 is composed of an arithmetic processing circuit such as a Central Processing Unit (CPU) and an integrated circuit such as a Field Programmable Gate Array (FPGA). The memory 102 is composed of a read only memory (ROM), a random access memory (RAM), a hard disk, and the like. Various programs and information are stored in the memory 102. These programs include a function for processing echo data to generate an image, and a program for causing the control circuit 101 (computer) to execute a function for determining a failure of the transducer 2.

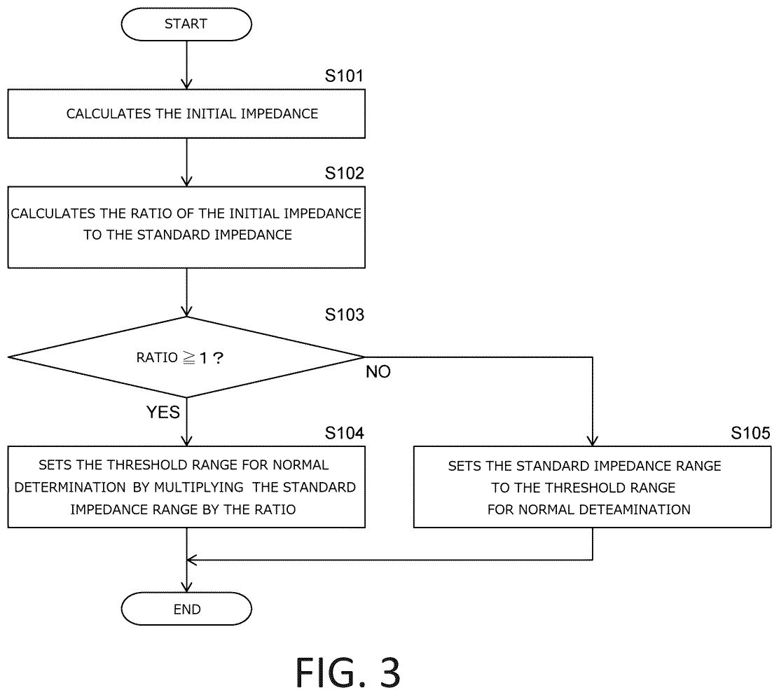

The memory 102 is also used as a work area in processing the control circuit 101. The control circuit 101 controls each part by a program stored in the memory 102. The processing for determining the failure of the transducer 2 will be described later with reference to FIGS. 3 to 6.

The memory 102 stores information about the standard impedance Zs of the same type transducer 2 and the standard impedance range ΔZs in which the same type transducer 2 is determined to be normal. This information is provided by the manufacturer of the transducer 2. The user may input this information from the input unit 106. Alternatively, this information may be held in a memory (not shown) in the transducer 2, and the control circuit 101 may acquire this information held in this memory from the transducer 2 at the time of initial communication with the transducer 2.

The input unit 106 is constituted by input means such as a mouse or a keyboard, and receives input from a user. The input unit 106 may be a touch panel integrated with the display unit 107. The display unit 107 is composed of a display such as a cathode-ray tube (CRT) monitor or a liquid crystal panel, and displays an image generated by the control circuit 101. As described above, the display unit 107 displays an echo image generated based on the echo data.

The control circuit 101 acquires echo data corresponding to depth and echo intensity for each transmission timing of the ultrasonic wave (transmission beam 3). The control circuit 101 generates an echo image on the basis of echo data for one frame continuously acquired, and causes the display unit 107 to display the echo image. The echo image is sometimes called an echogram.

An echo image is an image in which the echo intensity is distributed in a coordinate region with depth and time as two axes. In an echo image, each pixel is colored or shaded in a gradation corresponding to the signal intensity of the reflected wave. A user such as a fisherman may grasp the position and range of the fish group in the water by referring to the echo image displayed on the display unit 107.

The transmission voltage measuring circuit 109 measures the transmission voltage supplied from the transmission circuit 103 to the transducer 2 (ultrasonic oscillator 21). The transmission current measuring circuit 110 measures the transmission current supplied from the transmission circuit 103 to the transducer 2 (ultrasonic oscillator 21). The configuration of the transmission voltage measuring circuit 109 and the transmission current measuring circuit 110 is similar to that of the transmission voltage measuring circuit and the transmission current measuring circuit used for measuring the transmission voltage and the transmission current of the power supply circuit or the like. In the transmission voltage measuring circuit 109 and the transmission current measuring circuit 110, the parameters (resistance values, etc.) of each element are adjusted to conform to the magnitude of the transmission voltage and the transmission current that may be assumed to be supplied to the transducer 2 (ultrasonic oscillator 21).

In the present embodiment, a process for determining the failure of the transducer 2 is executed based on the transmission voltage and the transmission current measured by the transmission voltage measuring circuit 109 and the transmission current measuring circuit 110 and the echo strength based on the received signal. More specifically, the impedance of the transducer 2 is measured from the transmission voltage and the transmission current acquired in actual operation, and the existence of the failure of the transducer 2 is determined based on the measurement result and the echo strength.

FIG. 3 is a flowchart showing a threshold range setting process executed by the control circuit 101 in an initial operation.

Here, the initial operation refers to the timing at which the transducer 2 is driven substantially first after the transducer 2 and the fish finder 100 are installed on the ship 1. The initial operation may be the timing at which the transducer 2 is driven first, or the timing at which the transducer 2 is driven several days or weeks after the initial drive.

When the transducer 2 is replaced, the timing at which the transducer 2 is driven substantially first after replacement is the initial operation. In addition, when the fish finder 100 other than the transducer 2 is newly installed and the previous transducer 2 is used as it is, the timing at which the transducer 2 is driven substantially first thereafter is the initial operation.

The control circuit 101 calculates the initial impedance Z0 (transmission voltage/transmission current) of the transducer 2 from the transmission voltage and transmission current measured by the transmission voltage measuring circuit 109 and the transmission current measuring circuit 110, respectively, at the initial operation S101. The control circuit 101 refers to the standard impedance Zs of the transducer 2 stored in the memory 102 and calculates the ratio R0 of the initial impedance Z0 to the standard impedance Zs (That is, R0=Z0/Zs) (S102). The control circuit 101 determines whether the calculated ratio R0 is 1 or more (S103).

When the ratio R0 is 1 or more (S103: YES), then the control circuit 101 refers to the standard impedance range ΔZs stored in the memory 102, and sets the range in which the standard impedance range ΔZs is modified by the ratio R0 to the threshold range ΔZr for determining whether the transducer 2 is normal (S104). On the other hand, when the ratio R0 is less than 1 (S103: NO), then the control circuit 101 sets the standard impedance range ΔZs stored in the memory 102 as it is the threshold range ΔZr for determining normal (S105). The control circuit 101 stores the threshold range ΔZr set in step S104 or step S105 in the memory 102.

In step S104, the threshold range ΔZr is set by the following operations. That is, the intermediate value Zs0 of the impedance range ΔZs is multiplied by the ratio R0 to set the intermediate value Zr0 of the threshold range ΔZr. A range having the same width as the impedance range ΔZs around the intermediate value Zr0 is set as the threshold range ΔZr. For example, if the impedance range ΔZs is in the range ±ΔZ around the intermediate value Zs0, then the intermediate value Zr0 of the threshold range ΔZr is set to the value Zs0×R0, and the range ±ΔZ around the intermediate value Zr0 is set to the threshold range ΔZr.

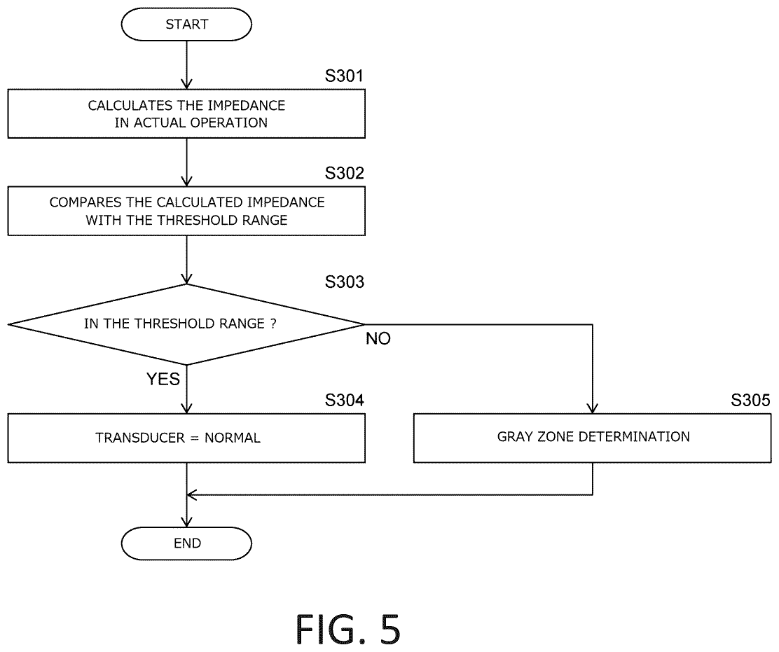

When the ratio R0 described above is less than 1, that is, when the initial impedance Z0 is smaller than the standard impedance Zs, then current flows more easily to the transducer 2 than when the standard impedance Zs is used, and damage to the transducer 2 is likely to occur. Therefore, even when the ratio R0 is less than 1, when the threshold range ΔZr is set by modifying the standard impedance range ΔZs by the ratio R0 in step S104, the set threshold range ΔZr also becomes smaller than the standard impedance range ΔZs, and it is easy to determine that the state in which a large current flows to the transducer 2 is normal in the determination process (first determination process) of FIG. 5 described later. As a result, the state in which the transducer 2 is considered normal after the processing of FIG. 5 becomes a state in which damage is likely to occur to the transducer 2.

To avoid such a problem, in the flowchart of FIG. 3, when the ratio R0 is less than 1 (S103: NO), then the standard impedance range ΔZs is set to the threshold range ΔZr for normal determination. As a result, it is possible to suppress the occurrence of damage to the transducer 2 caused by a large current flowing through the transducer 2.

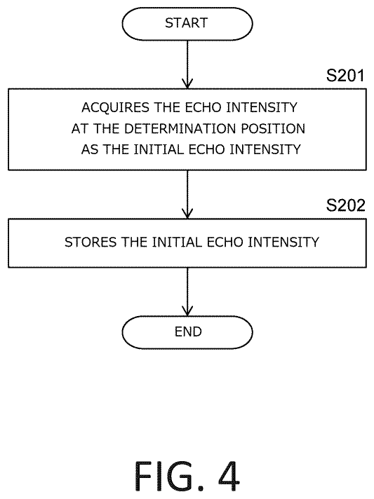

FIG. 4 is a flowchart showing the setting process of the initial echo intensity.

The control circuit 101 acquires the echo intensity based on the received signal initially output from the transducer 2 at a predetermined determination position (Longitude, Latitude) on the water (S201) as the initial echo intensity E0. The initial echo intensity E0 is acquired as the echo intensity from a predetermined depth (i.e., reference depth) when the ultrasonic wave is transmitted from the transducer 2 at a predetermined transmission power (reference transmission power). For example, the reference depth is the depth of the water bottom. In this case, the initial echo intensity E0 is the echo intensity of the reflected wave from the water bottom when the ultrasonic wave is transmitted with the reference transmission power. The control circuit 101 stores the acquired initial echo intensity E0 in the memory 102 (S202).

Here, the determination position in step S201 is preferably set at a position (Longitude, Latitude) on the route frequently passed by the ship 1 in which the fish finder 100 is installed. The determination position may be set based on the history of the position (Longitude, Latitude) detected by the position detecting unit 108 by the control circuit 101. Alternatively, the user may set the determination position manually. For example, the determination position may be the position (Longitude, Latitude) detected by the position detecting unit 108 at the timing when the user performs the setting input via the input unit 106 on the route frequently passed by the ship 1.

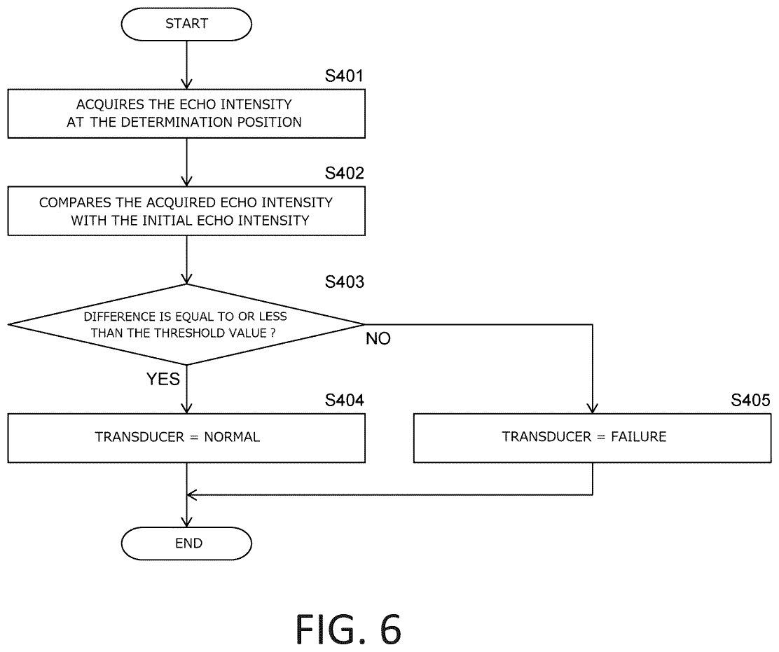

However, the determination position is preferably the position where the ship 1 stops, and more preferably the position where the ship 1 is normally moored in the port. In the state where the ship 1 stops, since the echo intensity is not easily affected by air bubbles, the environmental conditions under which the initial echo intensity E0 and the echo intensity Er are obtained may be brought close to each other. In addition, when the determination position is a mooring position in the port, the initial echo intensity E0 and the echo intensity Er may be obtained under almost the same environmental conditions. Therefore, the determination process (second determination process) of FIG. 6 described later may be performed with high accuracy.

In the case where the determination position is a mooring position, the determination position does not necessarily have to be specified as the position detected by the position detecting unit 108, and for example, it may be determined that the fish finder 100 and the transducer 2 are in the determination position in response to the user's activation of the fish finder 100 when preparing the ship 1 for departure.

The acquisition timing of the initial echo intensity E0 is the timing when the transducer 2 is first driven at the determination position and the reflected wave of the ultrasonic wave is received by the transducer 2 after the transducer 2 and the fish finder 100 are installed on the ship 1. When the transducer 2 is replaced, after the replacement the echo intensity acquired when the transducer 2 is first driven at the determination position is acquired as the initial echo intensity E0. Further, when the fish finder 100 other than the transducer 2 is newly installed and the previous transducer 2 is used as it is, the echo intensity acquired when the transducer 2 is first driven at the determination position is subsequently acquired as the initial echo intensity E0.

The setting of the initial impedance Z0 and the threshold range ΔZr in FIG. 3 and the acquisition and storage of the initial echo intensity E0 in FIG. 4 may be performed during the normal operation of the transducer 2 or may be performed at a timing different from the normal operation.

For example, when the processes are performed at the mooring position of the ship 1, i.e., when the mooring position is the determination position described above, the control circuit 101 transmits ultrasonic waves from the transducer 2 at the reference transmission power to obtain the initial impedance Z0 and the initial echo intensity E0 immediately after the fish finder 100 is activated for the processes. After the process, the control circuit 101 operates the transducer 2 in a normal operating state (transmission power).

When the acquisition process of the initial echo intensity E0 is performed in a normal operation, it is possible that the transmission power in the normal operation does not match the reference transmission power described above. In this case, based on the ratio between the transmission power and the reference transmission power in performing the process, the echo intensity (For example, echo intensity from the bottom of the water) acquired by the process is converted to an intensity corresponding to the reference transmission power. Then, the converted echo intensity is acquired as the initial echo intensity E0.

FIG. 5 is a flowchart showing a first determination process for determining whether the transducer 2 is normal based on the impedance of the transducer 2.

The control circuit 101 calculates the impedance Zr of the transducer 2 from the transmission voltage and the transmission current measured by the transmission voltage measuring circuit 109 and the transmission current measuring circuit 110, respectively, in the actual operation (S301), and compares the calculated impedance Zr with the threshold range ΔZr set by the process of FIG. 3 (S302). Here, the actual operation means a period during which the fish finder 100 performs normal operation after the initial setting operation shown in FIGS. 3 and 4 is completed.

When the impedance Zr is included in the threshold range ΔZr (S303: YES), the control circuit 101 determines that the transducer (2) is normal (S304). On the other hand, when the impedance Zr is not included in the threshold range ΔZr (S303: NO), the control circuit 101 determines that the transducer (2) is in the gray zone that has a possibility of failure (S305).

The control circuit 101 repeatedly executes the first determination process shown in FIG. 5 at a predetermined period during the actual operation of the fish finder 100. In each determination process, the control circuit 101 acquires the determination result in step S304 or the determination result in step S305. When the gray zone determination in step S305 is obtained in at least one of these determination processes, the control circuit 101 executes a second determination process based on the echo intensity.

Alternatively, when the gray zone determination in step S305 is repeatedly obtained a predetermined number of times or when the frequency of the gray zone determination in step S305 exceeds a predetermined threshold, the control circuit 101 may execute a second determination process based on the echo intensity on the assumption that a failure has likely occurred in the transducer 2.

FIG. 6 is a flowchart showing a second determination process for determining whether the transducer 2 is normal based on the echo intensity acquired from the received signal of the transducer 2.

In an actual operation, the control circuit 101 acquires the echo intensity Er based on the received signal from the transducer 2 at the determination position (S401).

For example, when the determination position is the mooring position, the control circuit 101 causes the transducer 2 to transmit at the reference transmission power at the timing when it is determined from the detection result of the position detecting unit 108 that the ship 1 has returned to the port and stopped at the mooring position. Alternatively, the control circuit 101 causes the transducer 2 to transmit at the reference transmission power at the timing when the fish finder 100 is activated at the time of the next departure after the ship 1 returns to the port and is moored and the power of the fish finder 100 is turned off. The control circuit 101 acquires the reference depth echo intensity (For example, echo intensity from the bottom of the water) as the actual operation echo intensity Er among the echo intensities based on the received signal output from the transducer 2 by the reflected wave of the transmission.

When the determination position is set on the route frequently passed by the ship 1, the control circuit 101 acquires the reference depth echo intensity (For example, echo intensity from the bottom of the water) based on the received signal output from the transducer 2 at the timing when the ship 1 reaches the determination position from the detection result of the position detecting unit 108 as the echo intensity Er in the actual operation.

In this case, if the transmission power of the transducer 2 at the determination position deviates from the reference transmission power, then the control circuit 101 converts the echo intensity (For example, echo intensity from the bottom of the water) of the reference depth acquired from the determination position to the intensity corresponding to the reference transmission power on the basis of the ratio between the transmission power and the reference transmission power. The control circuit 101 acquires the converted echo intensity as the echo intensity Er in the actual operation.

The control circuit 101 compares the acquired echo intensity Er with the initial echo intensity E0 acquired by the processing of FIG. 4 (S402). When the difference between the echo intensity Er and the initial echo intensity E0 is equal to or less than a predetermined threshold value (S403: YES), then the control circuit 101 determines that the transducer 2 is normal (S404). On the other hand, when the difference between the echo intensity Er and the initial echo intensity E0 is not equal to or less than this threshold value (S403: NO), then the control circuit 101 determines that the transducer 2 has failed (S405). As a result, the control circuit 101 terminates the processing shown in FIG. 6.

Here, the threshold value in step S403 is set to a value capable of determining whether a fault has occurred in the transducer 2. For example, if the difference between the echo intensity Er and the initial echo intensity E0 is obtained in decibels, then the threshold value Eth in step S403 may be obtained by the following equation using the upper limit value Zmax and the lower limit value Zmin of the standard impedance range ΔZs described above.

Eth=20 log 10(Zmax/Zmin) (1)

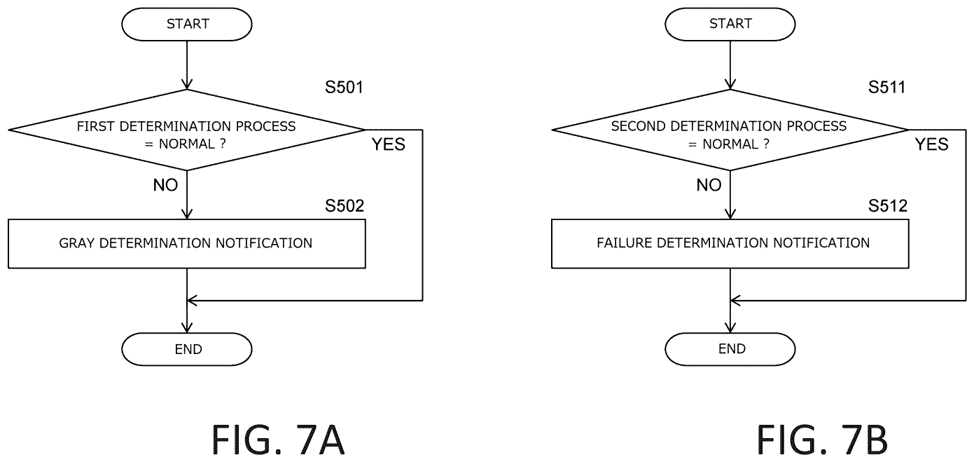

FIGS. 7A and 7B are flowcharts showing notification processing in the control circuit 101.

Referring to FIG. 7A, when the gray zone determination in step 305 is performed in the processing shown in FIG. 5 (S501: NO), then the control circuit 101 executes notification of the possibility of a failure in the transducer 2 (notification of the possibility of a failure) (S502). In this case, for example, the control circuit 101 causes a notification screen including a message of “There is a possibility of a failure in the transducer” to pop up on the screen displayed on the display unit 107. Thus, the user may grasp the possibility of a failure in the transducer 2.

Referring to FIG. 7B, in the process shown in FIG. 6, when the control circuit 101 performs the failure determination in step 405 (S511: NO), then the control circuit executes notification (notification about the failure) that the transducer 2 has failed (S512). In this case, for example, the control circuit 101 causes a notification screen including a message of “A failure has occurred in the transducer” to be displayed in a pop-up display on the screen displayed on the display unit 107. Thus, the user may grasp that a failure has occurred in the transducer 2.

The method of notification is not limited to the above example. For example, in step S502, a message “The transducer is about to fail” may be displayed. In step S502 and step S512, the background color of the notification screen may be changed. For example, the background color of the notification screen in step S502 may be set to yellow, and the background color of the notification screen in step S512 may be set to red, indicating that the notification in step S512 has a higher possibility of failure or needs to be dealt with.

Effect of Embodiment—According to this embodiment, the following effects may be achieved.

As shown in FIG. 2, the fish finder 100 (underwater detection device) includes the transmission voltage measuring circuit 109 for measuring the transmission voltage supplied to the transducer 2, the transmission current measuring circuit 110 for measuring the transmission current supplied to the transducer 2, and the control circuit 101. As shown in FIGS. 5 and 6, the control circuit 101 calculates the impedance Zr of the transducer 2 from the transmission voltage and the transmission current measured in actual operation (S301), and determines that a failure of the transducer 2 has occurred based on the determination that the transducer 2 are not normal (S303: NO, S403: NO) in both the first determination process (FIG. 5), which determines whether the transducer 2 are normal based on the calculated impedance Zr, and the second determination process (FIG. 6), which determines whether the transducer 2 are normal based on the echo intensity Er based on the received signal from the transducer 2 (S405).

The impedance of the transducer 2 and the echo intensity based on the received signal are subject to change depending on the operating environment of the transducer 2, such as conditions in water. Therefore, when the failure determination of the transducer 2 is made only by either the determination based on the impedance Zr or the determination based on the echo intensity Er, then the failure determination may be accurately made only by whether the impedance Zr or the echo intensity Er is abnormally high or low compared with the normal value. In other words, the occurrence of the failure may not be determined unless the defect is advanced considerably.

On the other hand, according to the fish finder 100 (underwater detection device) according to the present embodiment, the failure is determined to have occurred in the transducer 2 based on the fact that the transducer 2 may not be determined to be normal in the first determination process based on the impedance Zr of the transducer 2 and the transducer 2 may not be determined to be normal in the second determination process based on the echo intensity Er. As described above, since the two types of determination are used in a complementary manner, the presence or absence of a failure in the transducer 2 may be determined stably and appropriately without rigidly setting each determination criterion. Therefore, a failure in the transducer 2 may be determined early and stably.

As described with reference to FIGS. 5 and 6, when the first determination process in FIG. 5 fails to determine that the transducer 2 is normal (S305), then the control circuit 101 executes the second determination process in FIG. 6. Thus, when the first determination process in FIG. 5 determines that the transducer 2 is normal (S304), then the second determination process in FIG. 6 may not be executed. Thus, the determination process of the failure may be simplified while maintaining the accuracy of the failure determination.

As shown in FIGS. 3 and 5, the control circuit 101 calculates the initial impedance Z0 of the transducer 2 from the transmission voltage and the transmission current measured at the initial operation, and determines whether the transducer 2 is normal or not based on the impedance Zr obtained at the actual operation and the initial impedance Z0. According to this configuration, since the initial impedance Z0 measured at the initial operation is considered in the first determination process, the determination criterion (threshold range ΔZr) for failure due to the impedance Zr may be set appropriately in accordance with the inherent characteristic error of each transducer 2. Accordingly, the reliability of the first determination process may be enhanced, and as a result, the failure determination accuracy of the transducer 2 may be enhanced.

Specifically, as shown in FIG. 3, the control circuit 101 sets a threshold range ΔZr for determining that the transducer 2 is normal based on the initial impedance Z0 (S104, S105). In the first determination process shown in FIG. 5, the control circuit 101 determines whether the transducer 2 is normal based on whether the impedance Zr acquired in the actual operation is included in the threshold range ΔZr (S303). According to this configuration, it is possible to smoothly determine whether the transducer 2 is normal based on whether the impedance Zr acquired in the actual operation is included in the threshold range ΔZr set by considering the initial impedance Z0.

Here, as shown in FIG. 3, the control circuit 101 sets the threshold range ΔZr based on the standard impedance range ΔZs in which the transducer 2 is determined to be normal and the initial impedance Z0.

More specifically, when the ratio R0 of the initial impedance Z0 to the standard impedance Zs of the transducer 2 is 1 or more (S103: YES), then the control circuit 101 calculates the threshold range ΔZr by modifying the standard impedance range ΔZs by the ratio R0 (S104), and sets the standard impedance range ΔZs to the threshold range ΔZr when the ratio R0 of the initial impedance Z0 to the standard impedance Zs is less than 1 (S103: NO). Thus, as described above, the threshold range ΔZr may be set simply and appropriately using the standard impedance range ΔZs in which the transducer 2 is determined to be normal.

As shown in FIG. 4, the control circuit 101 acquires the echo intensity based on the received signal from the transducer 2 as the initial echo intensity E0 at a predetermined determination position on the water (S201), and determines whether the transducer 2 is normal or not based on the echo intensity Er acquired at the determination position in the actual operation and the initial echo intensity E0 in the second determination process of FIG. 6. According to this configuration, since the second determination process is performed based on the initial echo intensity and the echo intensity in the actual operation acquired from the same determination position at which environmental conditions are easily matched, it is possible to properly determine whether the transducer 2 is normal or not by the second determination process.

More specifically, in the second determination process shown in FIG. 6, the control circuit 101 determines whether the transducer 2 is normal or not based on whether the difference between the echo intensity Er acquired in the actual operation and the initial echo intensity E0 is less than or equal to a predetermined threshold value (S403). When a failure occurs in the transducer 2, then the difference between the echo intensity acquired in the initial operation and the echo intensity acquired in the actual operation tends to increase. Therefore, according to the above configuration, it is possible to smoothly determine whether the transducer 2 is normal or not.

As described above, the determination position is preferably the mooring position of the ship 1 where the fish finder 100 (underwater detection device) is installed. The mooring position of the ship 1 is relatively shallow, and the environmental conditions in the water are difficult to change. Therefore, since the mooring position of the ship 1 is set to the determination position as described above, the environmental conditions for obtaining the initial echo intensity E0 and the echo intensity Er in the actual operation may be matched more easily. Therefore, the second determination process based on the echo intensity Er may be performed with better accuracy, and as a result, the failure determination accuracy of the transducer 2 may be enhanced.

As shown in FIG. 7A, the control circuit 101 notifies the potentiality of the failure (S502) based on the first determination process could not determine to be normal (S501: NO), and as shown in FIG. 7B, the control circuit 101 notifies the failure (S512) based on the second determination process could not determine to be normal (S511: NO). According to these configurations, the user may grasp not only the occurrence of the failure but also the potentiality of the failure before the occurrence of the failure. Therefore, appropriate measures may be taken preparing for the failure of the transducer 2.

Modified Example—The present disclosure is not limited to the above embodiments. In addition, the embodiments of the present disclosure may be modified in various ways other than the above configuration.

For example, the first determination process is not necessarily limited to the process shown in FIG. 5, but may be changed to another process. For example, it may be determined that the transducer 2 is not normal when the impedance Zr in the actual operation is not included in the threshold range ΔZr for a predetermined number of consecutive times, or it may be determined that the transducer 2 is not normal when the frequency at which the impedance Zr in the actual operation is not included in the threshold range ΔZr exceeds the predetermined threshold.

Further, in the above embodiment, in the first determination process, it is determined whether the transducer 2 is normal according to whether the impedance Zr in the actual operation is included in the threshold range ΔZr, but in the first determination process, it may be determined that the transducer 2 is normal if the difference between the impedance Zr in the actual operation and the initial impedance Z0 is less than or equal to the predetermined threshold, and it may be determined that the transducer 2 is not normal if the difference exceeds this threshold. In this case, the threshold may be set to a value capable of determining whether the transducer 2 is normal according to this difference.

The second determination process is not necessarily limited to the process shown in FIG. 6, and may be changed to another process. For example, it may be determined that the transducer 2 is not normal when the difference between the echo intensity Er and the initial echo intensity E0 in the actual operation continuously exceeds the threshold value Eth a predetermined number of times, or it may be determined that the transducer 2 is not normal when the frequency at which the difference between the echo intensity Er and the initial echo intensity E0 in the actual operation exceeds the threshold value Eth exceeds the predetermined threshold value.

In addition, in the above embodiment, according to the determination that the transducer 2 is not normal by the first determination process, a notification concerning the possibility of failure is given by the process shown in FIG. 7A, but a notification concerning the possibility of failure may be given when the determination that the transducer 2 is not normal by the first determination process continuously occurs a predetermined number of times, or a notification concerning the possibility of failure may be given when the frequency at which the transducer 2 is determined not to be normal by the first determination process exceeds the predetermined threshold value.

In the above embodiment, when the determination in the first determination process shown in FIG. 5 becomes a gray zone determination, the second determination process shown in FIG. 6 is performed to determine whether a failure has occurred in the transducer 2, but both the first determination process and the second determination process may be performed to determine the failure of the transducer 2.

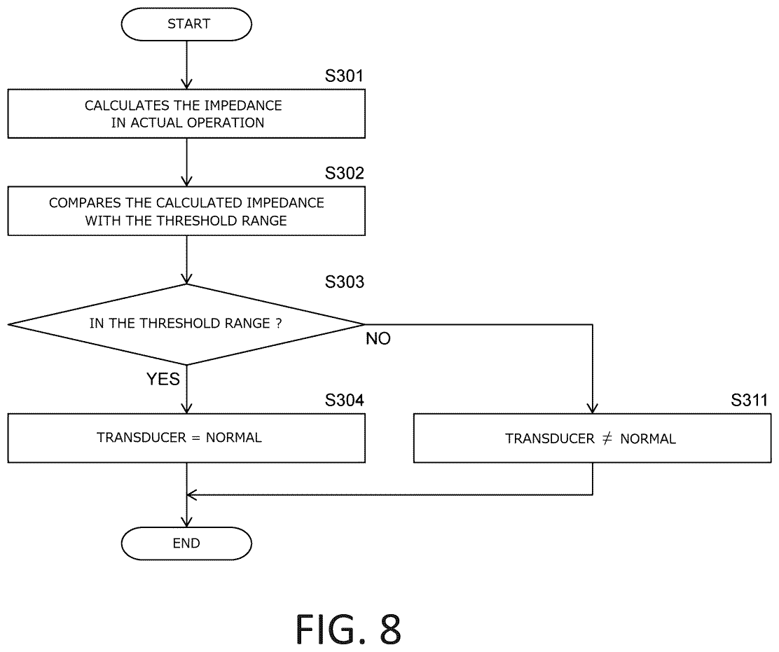

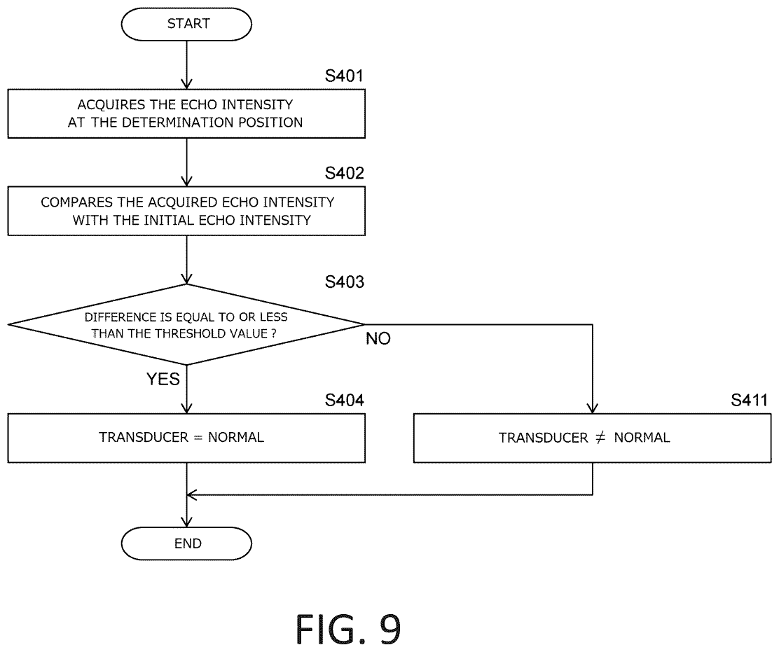

In this case, for example, the first determination process is changed as shown in FIG. 8, and the second determination process is changed as shown in FIG. 9. In the process shown in FIG. 8, if the determination in step S303 is NO, then it is determined that the transducer 2 is not normal (S311), and in the process shown in FIG. 9, if the determination in step S403 is NO, then it is determined that the transducer 2 is not normal (S411). The control circuit 101 determines that the transducer 2 has failed when both the determination results in step S311 and step S411 are obtained in one sequence from the start of the fish finder 100 to the end of operation (power off), for example. Alternatively, it may be determined that the transducer 2 has failed when the determination result in step S311 is obtained by the first determination process in one sequence and the determination result in step S411 is obtained by the second determination process in the sequence immediately before or after this sequence.

The method for setting the threshold range ΔZr is not limited to the method shown in FIG. 3 and may be changed accordingly. For example, the threshold range ΔZr may be calculated by multiplying the standard impedance range ΔZs by a value obtained by multiplying the ratio R0 by a predetermined coefficient. In this case, the coefficient when the ratio R0 is less than 1 may be adjusted to be less than the coefficient when the ratio R0 is 1 or more, and the threshold range ΔZr may be uniformly calculated by this calculation method regardless of whether the ratio R0 is 1 or more. In addition, the coefficient may change according to the ratio R0, such as reducing the coefficient as the ratio R0 becomes smaller.

In the above embodiment, the mooring position in the port is shown as an example of the determination position in the processing of FIG. 4, but the determination position is not limited to this. For example, when a captured fish is transferred to an offshore fish tank, the position where the ship (1) is placed alongside the fish tank may be set as the determination position. The control circuit 101 may obtain the position where the ship 1 frequently stops from the history of the position information where the ship 1 stops information from the position detecting unit 108, and set the position as the determination position.

The determination position may not be limited to one but may be set to a plurality. In this case, after the determination in step S305 of FIG. 5 has been made, the processing shown in FIG. 6 may be performed every time the ship 10 (fish finder 100) reaches the determination position. If the processing shown in FIG. 6 is performed at a plurality of determination positions in a sequence from the start of the fish finder 100 to the end of the operation (i.e., power off), it may be determined that the transducer 2 has failed because the determination in step S405 has been obtained at any one of them. Alternatively, it may be determined that the transducer 2 has failed due to the determination in step S405 at a plurality of the determination positions. Similarly, the processing shown in FIG. 9 may be performed at a timing when the ship 1 reaches each determination position.

In FIG. 2, only one ultrasonic oscillator 21 is disposed in the transducer 2, but a plurality of ultrasonic oscillators may be disposed in the transducer 2. In this case, a transmission voltage measuring circuit and a transmission current measuring circuit are provided for each ultrasonic oscillator, and the first determination process and the second determination process are performed for each ultrasonic oscillator.

In the above embodiment, an example of the application of the present disclosure to the fish finder 100 mounted on the ship 1 is shown, but the application of the present disclosure is not limited to this. For example, the present disclosure may be applied to a fish finder installed on a set net, or it may be applied to an underwater detection device other than a fish finder such as a scanning sonar.

In addition, embodiments of the present disclosure may be suitably modified to the extent described in the claims.

### Terminology

It is to be understood that not necessarily all objects or advantages may be achieved in accordance with any particular embodiment described herein. Thus, for example, those skilled in the art will recognize that certain embodiments may be configured to operate in a manner that achieves or optimizes one advantage or group of advantages as taught herein without necessarily achieving other objects or advantages as may be taught or suggested herein.

All of the processes described herein may be embodied in, and fully automated via, software code modules executed by a computing system that includes one or more computers or processors. The code modules may be stored in any type of non-transitory computer-readable medium or other computer storage device. Some or all the methods may be embodied in specialized computer hardware.

Many other variations than those described herein will be apparent from this disclosure. For example, depending on the embodiment, certain acts, events, or functions of any of the algorithms described herein can be performed in a different sequence, can be added, merged, or left out altogether (e.g., not all described acts or events are necessary for the practice of the algorithms). Moreover, in certain embodiments, acts or events can be performed concurrently, e.g., through multi-threaded processing, interrupt processing, or multiple processors or processor cores or on other parallel architectures, rather than sequentially. In addition, different tasks or processes can be performed by different machines and/or computing systems that can function together.

The various illustrative logical blocks and modules described in connection with the embodiments disclosed herein can be implemented or performed by a machine, such as a processor. A processor can be a microprocessor, but in the alternative, the processor can be a controller, microcontroller, or state machine, combinations of the same, or the like. A processor can include electrical circuitry configured to process computer-executable instructions. In another embodiment, a processor includes an application specific integrated circuit (ASIC), a field programmable gate array (FPGA) or other programmable device that performs logic operations without processing computer-executable instructions. A processor can also be implemented as a combination of computing devices, e.g., a combination of a digital signal processor (DSP) and a microprocessor, a plurality of microprocessors, one or more microprocessors in conjunction with a DSP core, or any other such configuration. Although described herein primarily with respect to digital technology, a processor may also include primarily analog components. For example, some or all of the signal processing algorithms described herein may be implemented in analog circuitry or mixed analog and digital circuitry. A computing environment can include any type of computer system, including, but not limited to, a computer system based on a microprocessor, a mainframe computer, a digital signal processor, a portable computing device, a device controller, or a computational engine within an appliance, to name a few.

Conditional language such as, among others, “can,” “could,” “might” or “may,” unless specifically stated otherwise, are otherwise understood within the context as used in general to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without user input or prompting, whether these features, elements and/or steps are included or are to be performed in any particular embodiment.

Disjunctive language such as the phrase “at least one of X, Y, or Z,” unless specifically stated otherwise, is otherwise understood with the context as used in general to present that an item, term, etc., may be either X, Y, or Z, or any combination thereof (e.g., X, Y, and/or Z). Thus, such disjunctive language is not generally intended to, and should not, imply that certain embodiments require at least one of X, at least one of Y, or at least one of Z to each be present.

Any process descriptions, elements or blocks in the flow diagrams described herein and/or depicted in the attached figures should be understood as potentially representing modules, segments, or portions of code which include one or more executable instructions for implementing specific logical functions or elements in the process. Alternate implementations are included within the scope of the embodiments described herein in which elements or functions may be deleted, executed out of order from that shown, or discussed, including substantially concurrently or in reverse order, depending on the functionality involved as would be understood by those skilled in the art.

Unless otherwise explicitly stated, articles such as “a” or “an” should generally be interpreted to include one or more described items. Accordingly, phrases such as “a device configured to” are intended to include one or more recited devices. Such one or more recited devices can also be collectively configured to carry out the stated recitations. For example, “a processor configured to carry out recitations A, B and C” can include a first processor configured to carry out recitation A working in conjunction with a second processor configured to carry out recitations B and C. The same holds true for the use of definite articles used to introduce embodiment recitations. In addition, even if a specific number of an introduced embodiment recitation is explicitly recited, those skilled in the art will recognize that such recitation should typically be interpreted to mean at least the recited number (e.g., the bare recitation of “two recitations,” without other modifiers, typically means at least two recitations, or two or more recitations).

It will be understood by those within the art that, in general, terms used herein, are generally intended as “open” terms (e.g., the term “including” should be interpreted as “including but not limited to,” the term “having” should be interpreted as “having at least,” the term “includes” should be interpreted as “includes but is not limited to,” etc.).

For expository purposes, the term “horizontal” as used herein is defined as a plane parallel to the plane or surface of the floor of the area in which the system being described is used or the method being described is performed, regardless of its orientation. The term “floor” can be interchanged with the term “ground” or “water surface.” The term “vertical” refers to a direction perpendicular to the horizontal as just defined. Terms such as “above,” “below,” “bottom,” “top,” “side,” “higher,” “lower,” “upper,” “over,” and “under,” are defined with respect to the horizontal plane.

As used herein, the terms “attached,” “connected,” “mated” and other such relational terms should be construed, unless otherwise noted, to include removable, moveable, fixed, adjustable, and/or releasable connections or attachments. The connections/attachments can include direct connections and/or connections having intermediate structure between the two components discussed.

Numbers preceded by a term such as “approximately,” “about,” and “substantially” as used herein include the recited numbers, and also represent an amount close to the stated amount that still performs a desired function or achieves a desired result. For example, the terms “approximately,” “about,” and “substantially” may refer to an amount that is within less than 10% of the stated amount. Features of embodiments disclosed herein preceded by a term such as “approximately,” “about,” and “substantially” as used herein represent the feature with some variability that still performs a desired function or achieves a desired result for that feature.

It should be emphasized that many variations and modifications may be made to the above-described embodiments, the elements of which are to be understood as being among other acceptable examples. All such modifications and variations are intended to be included herein within the scope of this disclosure and protected by the following claims.

1. An underwater detection device, comprising:
processing circuitry configured to:
measure a transmission voltage supplied to a transducer;
measure a transmission current supplied to the transducer;
calculate an impedance of the transducer from the transmission voltage and the transmission current measured in an actual operation; and
determine that a failure of the transducer has occurred based on determining that the transducer is not normal in both a first determination process for determining whether the transducer is normal or not based on the impedance and a second determination process for determining whether the transducer is normal or not based on an echo intensity based on a received signal from the transducer.

2. The underwater detection device according to claim 1, wherein:
the processing circuitry configured to execute the second determination process when the transducer may not be determined to be normal by the first determination process.

3. The underwater detection device according to claim 1, wherein:
the processing circuitry configured to:
calculate an initial impedance of the transducer from the transmission voltage and the transmission current measured at a time of an initial operation; and
determine whether the transducer is normal or not based on the impedance acquired at the time of actual operation and the initial impedance in the first determination process.

4. The underwater detection device according to claim 3, wherein:
the processing circuitry configured to:
set a threshold range for determining that the transducer is normal based on the initial impedance; and
in the first determination process, determine whether the transducer is normal based on whether the impedance acquired during the actual operation is included in the threshold range.

5. The underwater detection device according to claim 4, wherein:
the processing circuitry configured to set the threshold range on a basis of a standard impedance range in which the transducer is determined to be normal and the initial impedance.

6. The underwater detection device according to claim 5, wherein:
the processing circuitry configured to:
if a ratio of the initial impedance to the standard impedance is equal to or greater than 1, calculate the threshold range by modifying the standard impedance range by the ratio; and
if the ratio of the initial impedance to the standard impedance is less than 1, set the standard impedance range to the threshold range.

7. The underwater detection device according to claim 1, wherein:
the processing circuitry configured to:
at a predetermined determination position on the water, acquire the echo intensity based on the received signal from the transducer as the initial echo intensity; and
in the second determination process, determine whether the transducer is normal based on the echo intensity acquired at the determination position during the actual operation and the initial echo intensity.

8. The underwater detection device according to claim 7, wherein:
the processing circuitry configured to determine whether the transducer is normal based on whether a difference between the echo intensity acquired during the actual operation and the initial echo is equal to or less than a predetermined threshold.

9. The underwater detection device according to claim 8, wherein:
the determination position is a mooring position of a ship on which the underwater detection device is installed.

10. The underwater detection device according to claim 2, wherein:
the processing circuitry configured to:
notify a possibility of a failure based on may not determine normal in the first determination process; and
notify a failure based on may not determine normal in the second determination process.

11. A failure determination method of a transducer executed by an underwater detection device, comprising:
measuring a transmission voltage and a transmission current supplied to the transducer in actual operation;
calculating an impedance of the transducer from the transmission voltage and the transmission current; and
determining that a failure of the transducer has occurred based on determining that the transducer is not normal in both a first determination process for determining whether the transducer is normal or not based on the impedance and a second determination process for determining whether the transducer is normal or not based on an echo intensity based on a received signal from the transducer.

12. A non-transitory computer-readable medium having stored thereon computer-executable instructions which, when executed by a computer of an underwater detection device cause the computer of the underwater detection device to execute a function of:
measuring a transmission voltage and a transmission current supplied to the transducer in actual operation;
calculating an impedance of the transducer from the transmission voltage and the transmission current; and
determining that a failure of the transducer has occurred based on determining that the transducer is not normal in both a first determination process for determining whether the transducer is normal or not based on the impedance and a second determination process for determining whether the transducer is normal or not based on an echo intensity based on a received signal from the transducer.
